(19) United States
(12) Patent Application Publication
(10) Pub. No.: US 2023/0389433 A1
(43) Pub. Date: Nov. 30, 2023

(54) FLEXIBLE ORGANIC ELECTROCHEMICAL TRANSISTORS AS BENDING SENSORS

(71) Applicant: KENT STATE UNIVERSITY, Kent, OH (US)

(72) Inventors: Vikash KAPHLE, Hattiesburg, MS (US); Chathuranga P.H. RAJAPAKSHA, Kent, OH (US); Björn LÜSSEM, Bremen (DE); Pushpa Raj PAUDEL, Kent, OH (US); Antal JÁKLI, Kent, OH (US); Thein KYU, Akron, OH (US)

(21) Appl. No.: 18/027,724

(22) PCT Filed: Oct. 13, 2021
(86) PCT No.: PCT/US2021/054726

§ 371 Date: Mar. 22, 2023

Related U.S. Application Data
(60) Provisional application No. 63/091,446, filed on Oct. 14, 2020.

(51) Int. Cl. H10N 30/857; H10N 30/30

(52) U.S. Cl. CPC H10N 30/857; H10N 30/302; H10N 30/50

(57) ABSTRACT

Organic Electrochemical Transistors (OECTs) have the potential to enable fully flexible low-cost electronics. Combining OECTs with ionic electroactive polymers (IEAP) yields a highly sensitive bending sensors with respect to mechanical bending. In comparison the proposed sensor has a sensitivity that is several orders of magnitude larger than conventional electroactive polymers.

### FIELD OF THE INVENTION

The invention generally relates to combining organic electrochemical transistors (OECTs) with ionic electroactive polymers (IEAPs) to obtain highly sensitive bending sensors.

### BACKGROUND OF THE INVENTION

Current bending sensors based on ionic electroactive polymers (IEAPs) generate very low currents (in the range of nanoampere), for example from about 20 nA to about 200 nA, and more likely from about 60 nA to about 140 nA nano amperes, that is hard to detect in real life situations. Accordingly, there is a need to provide a higher signal and to increase the signal to noise ratio of strain sensors.

### SUMMARY OF THE INVENTION

Organic Electrochemical Transistors (OECTs) have the potential to enable fully flexible low-cost electronics. In this invention, an ionic electroactive polymer (IEAP) is used to make OECTs sensitive to mechanical bending. Compared to other curvature sensors, this sensor inherently amplifies the signal caused by bending, which results in a larger sensitivity. Furthermore, the present invention allows to discriminate the bending direction, i.e. the proposed device can be used to distinguish between upward and downward bending.

The present invention opens new approaches for artificial skin and or data glove applications. In particular, the high mechanical flexibility, high sensitivity, and the potential to combine this mechanical sensor with other chemical sensors (in the same device) will enable new designs for the broader field of wearable electronics.

### BRIEF DESCRIPTION OF THE DRAWINGS

The invention will be better understood, and other features and advantages will become apparent by reading the detailed description of the invention, taken together with the drawings, wherein:

FIG. 1(a) relates to the fact that IEAPs are responsive to an applied electric field. The field forces anions and cations of the ionic liquid thereof to move to opposite sides of the film. If the two ionic species of the IEAP differ in size, the cantilever bends. FIG. 1(b) relates to the molecular structure of the IEAP elastomer used. FIG. 1(c) relates to the electric response of the elastomer in (b) to mechanical excitation with varying waveforms.

FIG. 2 relates to a device setup for (a) Dielectric elastomer actuator, (b) Organic Electrochemical Transistors (OECT) based on IEAP. The “source”, “drain”, and “gate” blocks represent contacts formed by copper strips. The central finely dotted gray area of FIGS. 2(a) and (b) is the ionic electroactive polymer (IEAP), e.g. the mixture shown in FIG. 1(b) based on poly (ethylene glycol) diacrylate (PEGDA). The solid black line that forms an upper and lower boarder of the IEAP is a thin layer of an organic semiconductor, e.g. PEDOT:PSS. The arrangement of source, drain, gate electrode, the PEDOT:PSS layer, and the IEAP layer is akin to an Organic Electrochemical Transistor with the IEAP layer taking the function of the electrolyte. The force generator moves the right side of the cantilever up and down, which generates an ion current flowing vertically in the device.

FIG. 3(a) relates to transfer and FIG. 3(b) relates to the Output characteristics of the OECT based on IEAP shown in FIG. 1(b) wherein an external force is applied to the right end; FIG. (c) relates to amplification of flexo-currents by the transistor.

FIG. 4(a) relates to curvature sensors based on the Ionic Liquid Crystal Elastomer, FIG. 4(b) shows the transfer characteristic of the device, FIGS. 4(c) and 4(d) displays the response of the system to upward (c) or downward (d) bending.

### DETAILED DESCRIPTION OF THE INVENTION

Organic Electrochemical Transistors (OECTs) have potential to enable fully flexible low-cost electronics. OECTs can be combined with ionic electroactive polymers (IEAPs) to realize highly sensitive bending sensors.

Bending or flex sensors are widely used and essential for many robotics applications. They are used in goniometric gloves² or are envisioned for artificial skin applications. Current bend sensors fall into different categories: sensors that are based on a change in resistance due to a strain in the device, fiber optic sensors based on a change in transmission upon bending, bend sensors based on electroactive, often piezoelectric, polymers, or capacitive sensors. However, all approaches have their own limitations. Strain sensors are inherently susceptible to cracks in the active layer and a low lifetime, Fiber optic sensors require dedicated read-out electronics and are challenging to miniaturize.

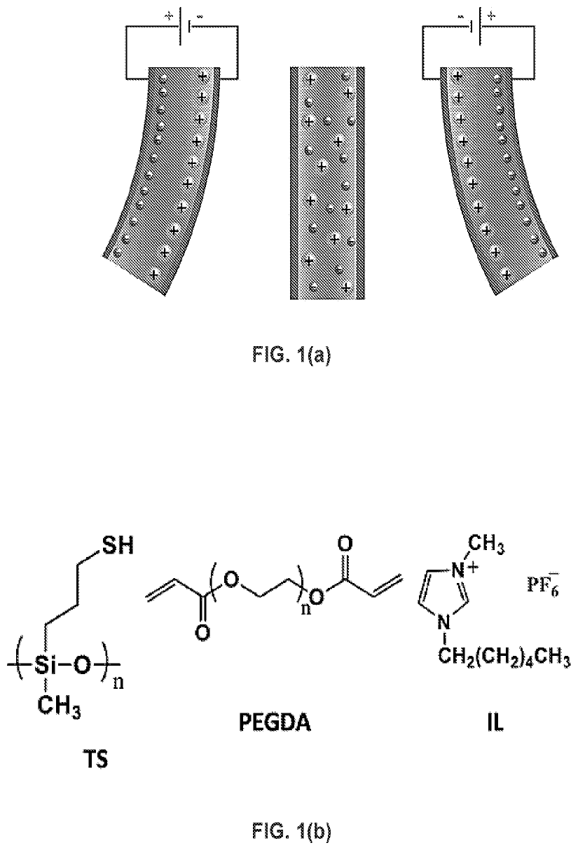

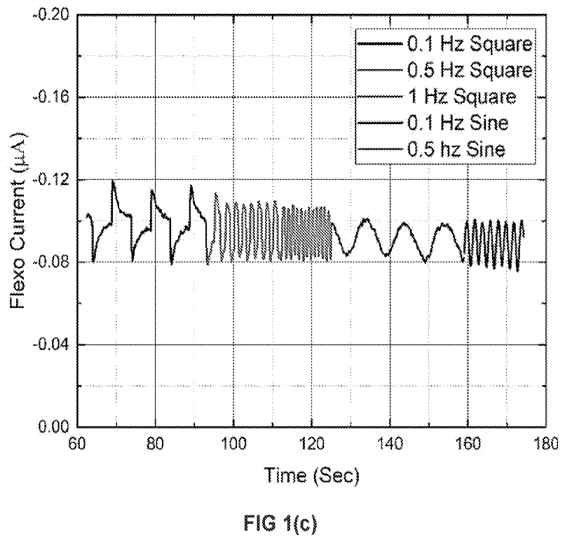

Ionic electroactive polymers (IEAPs) are a subclass of electroactive polymers that are known to deflect when an electric field is applied and current flows across the film (cf. FIG. 1(a). The IEAPs of the present invention generally comprise an ionic electroactive polymer, and an ionic liquid, a photoinitiator, and a crosslinking agent. The ionic liquid generally contains ions, i.e. cations, and anions of different sizes. An electric field applied to the film forces cations and anions to move to opposite sides of the polymer. If the different ions are of different size, Maxwell's stress is generated in the layer, which is responsible for bending of the elastomer. This process is reversible: if a mechanical force is applied to bend the elastomer, cations and anions are driven to opposite sides of the polymer, which results in a current through the system known as flexo-ionic (or simply “flexo”) current.

IEAP Polymer

Ionic electroactive polymers are polymers that exhibit a change in size or shape when stimulated by an electric field. As noted above, the most common applications of these types of polymers are in actuators or sensors. A typical characteristic property of an IEAP is that they undergo a large amount of deformation while withstanding large forces.

Different types of IEAP polymers can be utilized in the present invention including Nafion (N-(3-acetylphenyl)-4-(2-phenylethyl)thieno[3,2-b]pyrrole-5-carboxamide), Aquivion (Tetrafluoroethylene-perfluoro(3-oxa-4-pentenesulfonic acid) copolymer), PMMA (Poly (methyl methacrylate)), PVDF (Polyvinylidene fluoride), Pluronic, Polyacrylamide, PDMS (polydimethylsiloxane), poly(ethylene glycol) methyl ether acrylate, or PANI (polyaniline), or any combination thereof.

A preferred type of IEAP polymer is a poly(ethylene glycol)diacrylate (PEGDA) which is the chemical reaction of a monomer; a crosslinking agent; an initiator and an ionic liquid. In some embodiments, the monomer is an acrylate monomer, such as a monofunctional acrylate monomer. The use of an initiator is optional. The monofunctional acrylate monomer can be

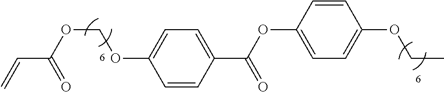

The crosslinking agent can be a bifunctional crosslinking agent. In some embodiments, the bifunctional crosslinking agent is

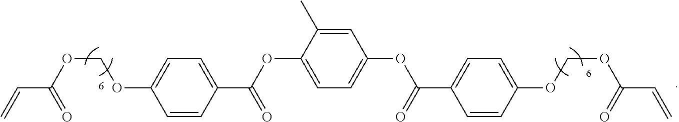

The initiator may be a photoinitiator. In some embodiments, the photoinitiator is

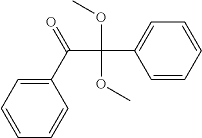 [SMILES: COC(OC)(C(=O)c1ccccc1)c1ccccc1]

The ionic liquid can be

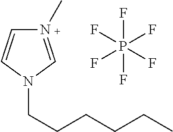

That is 1-hexyl-3-methylimidazolium hexafluorophosphate) that consists of cations and anions of different size. In this case: PF₆₋ is anion which is smaller as compared to the cations.

Some other monomers which can be used are 4-(6-acryloyloxylhexyloxy)phenyl 4-(6-acryloyloxylhexyloxy)benzoate, 1-4-di(4-(6-acryloyloxyhexyloxy) benzoyloxy)cyclohexane, 1-4-phenylene bis(4-(6-(vinyloxy) hexyloxy)benzoate) and 4-cyanophenyl 4-((6-(acryloyloxy)hexyl)oxy)benzoate. Some other photo initiators that can be used are Irgacure 819, Irgacure 2959, etc. Some other ionic liquids that can be used are [DMIM][CI] (1-decyl 3-methyl imidazolium chloride), EAN (ethyl ammonium nitrate), [Li][TFSI] (lithium bis(trifluoromethanesulfonyl) imide)), [BMI][BF4]1-Butyl-3-methylimidazolium tetrafluoroborate, etc.

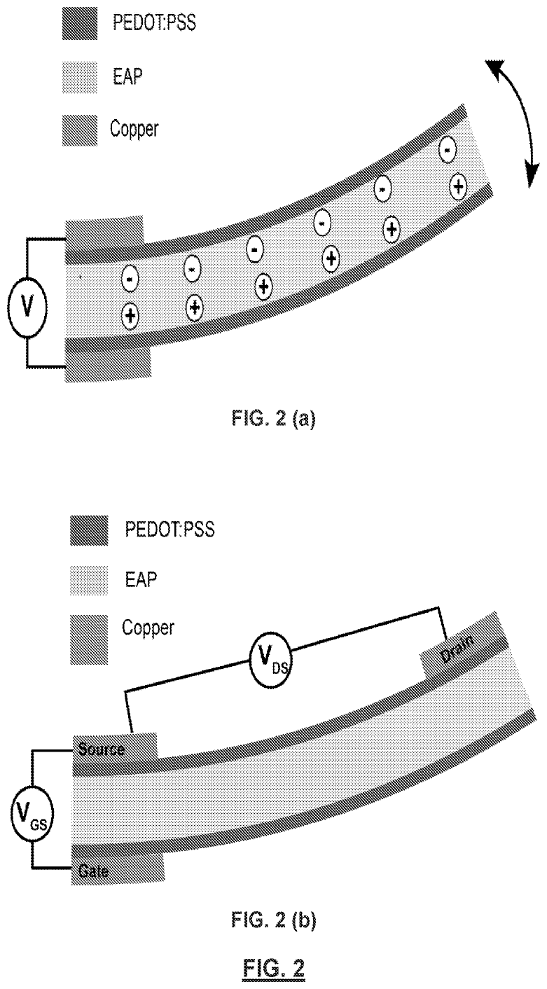

The organic electrochemical transistor (OECT) of the present invention is the embodiment set forth in FIG. 2b of the present invention wherein the center layer thereof, e.g. a laminate or an encapsulated IEAP, is the above-noted ionic electroactive polymer that is generally a flexible solid. The upper and lower thin layers that comprise various polymers such as Poly(3-hexylthiophene) (P3HT); poly(2-(3,3′-bis(diethylene glycol monomethyl ether)-[2,2′-bithiophen]-5-yl))-(2-(3,3′-bis(tetraethylene glycol monomethyl ether)-[2,2′-bithiophen]-5-yl)) (p(g2T2-g4T2)); poly{[N,N′-bis(2-octyldodecyl)naphthalene-1,4,5,8-bis(dicarboximide)-2,6-diyl]-alt-5,5′-(2,2′-bithiophene)-ran-[N,N′-bis(7-glycol)naphthalene-1,4,5,8-bis(dicarboximide)-2,6-diyl]-alt-5,5′-(2,2′-bithiophene)}(P90); poly(2-(3,3-bis(2-(2-(2-methoxyethoxy)ethoxy)ethoxy)-[2,2′-bithiophen]-5-yl)thieno[3,2-b]thiophene) (p(g2T-TT)); poly(3-{[2-(2-methoxyethoxy)ethoxy]methyl}thiophene-2,5-diyl) (P3MEEMT); and preferably PEDOT;PSS, i.e. poly(3,4-ethylenedioxythiophene) polystyrene sulfonate, that is Highly dopped p-type conducting polymer, or any combination thereof. Desirably an electrolyte is also contained within the OECT such as sodium chloride, potassium chloride, 1-Ethyl-3-methylimidazolium ethyl sulfate [EMIM][ESO4], and the like, and also to form the overall organic electrochemical transistors of the present invention as shown in FIG. 2b.

### EXAMPLE

In FIG. 1c, an example for a flexo-current is displayed. The IEAP used (FIG. 1b) comprises of poly (ethylene glycol) diacrylate (PEGDA), thiosiloxane (TS) and the ionic liquid (1-hexyl-3-methylimidazolium hexafluorophosphate) (IL). The ionic liquid comprises cations and anions of different size. In this case: PF₆₋ is an anion that is smaller as compared to the cations. The polymer is crosslinked via a so-called thiolene ‘click’ reaction between thiol (SH) of TS and the C═C double bonds of functional acrylate groups of the PEGDA backbone. The preparation thereof is known to the art and to the literature.

Generally, sensors can have any shape or size such as from about 0.1 cm to about 10 cm long, and desirably from about 1 cm to about 3 cm long; generally from about 0.1 cm to about 5 cm wide, and desirably from about 0.3 cm to about 2 cm wide; and generally with a thickness of from generally about 100 μm to about 2000 μm and desirably with a thickness of from about 200 μm to about 500 μm thick. With regard to the present example, a 1 cm long, 0.5 cm wide, and about 200 μm thick polymer cantilever strip is cut from the IEAP.

The polymer PEDOT:PSS is spin coated on either side of the polymer strip to form flexible electrodes. The general thickness of the spin coating is from about 50 nm to about 200 nm units and desirably from about 80 to about 120 nm units. One component is the coating made up of sodium polystyrene sulfonate which is a sulfonated polystyrene. Part of the sulfonyl groups are deprotonated and carry a negative charge. The other coating, i.e. the organic semi-conductor, e.g. poly(3,4-ethylenedioxythiophene) (PEDOT) is a conjugated polymer and carries positive charges and is based on polythiophene. Together the charged macromolecules form a macromolecular salt. Copper strips are used to define contacts on the top and bottom of the device. The setup shown in FIG. 2a is used to bend the elastomer periodically at the right of the cantilever.

To measure the flexo-current, top and bottom electrodes are held at the same potential and the flexo-current generated by the mechanical force is measured (cf. FIG, 2a). A deflection of approx. 5 mm is imposed on the right of the sample following various waveforms and frequencies. It was observed that the flexo-current follows the external frequency as well as the waveform of the generator.

However, the flexo-current is small i.e. in the range of from about 80 nano ampere to about 120 nano amperes and it is necessary to amplify this current in order to realize a sensitive curvature sensor. This invention presents a solution to this problem. To include gain into the sensor and to amplify flexo-currents generated by the elastomer, IEAP is combined with an organic electrochemical transistor (OECT) in a configuration, for examinate, as shown in FIG. 2b. The two electrodes at one end of the device are used as source and gate and a third electrode used as a drain is defined at the other end of the sensor. In this OECT setup it is possible to tune the current flowing from the source and to the drain contact through the top PEDOT:PSS layer. When a positive voltage is applied to the gate electrode on the bottom of the OECT, cations from the electrolyte move into the top PEDOT:PSS layer, The cations de-dope the PEDOT:PSS layer, which reduces its conductivity and the current flowing through this film.

As seen in FIG. 2a the ions in the IEAP will respond to mechanical bending the device as well. By bending the OECT upwards or downwards, cations will either be injected into or removed from the top PEDOT layer, which again will result in a large change in current flowing from source to drain.

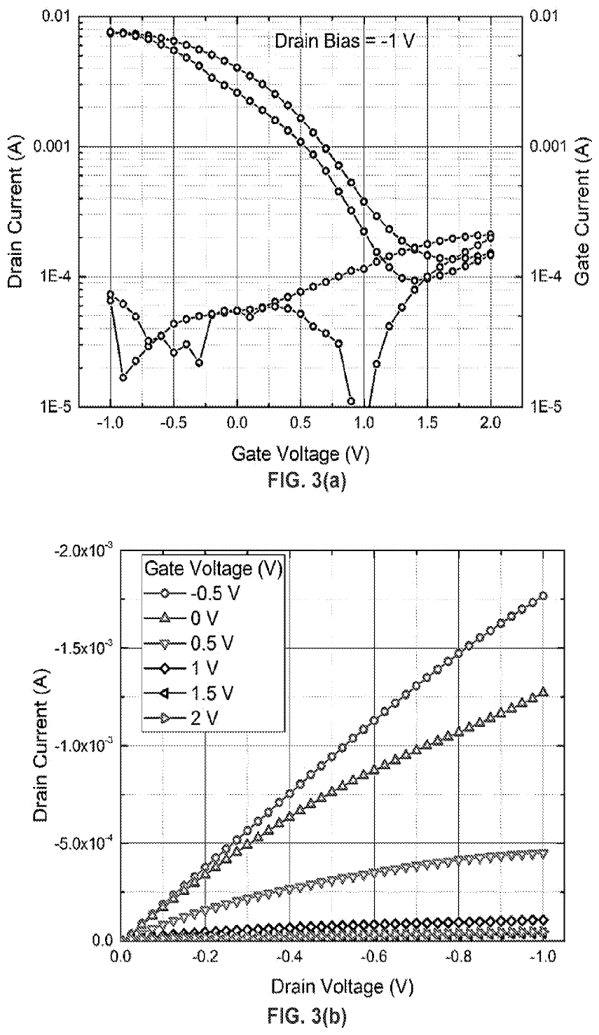

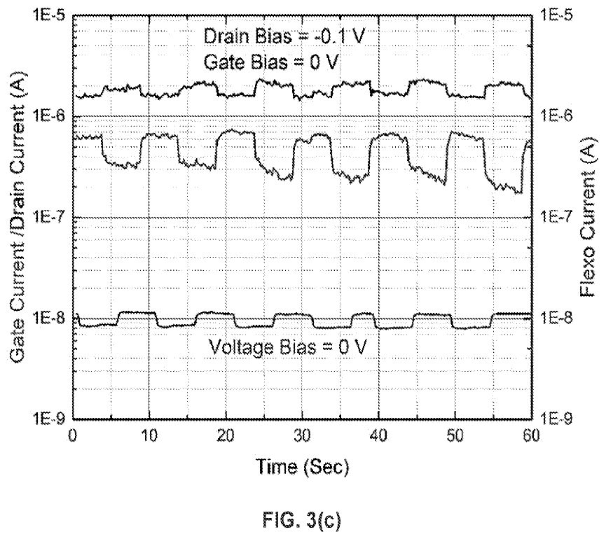

An embodiment of this invention is shown in FIG. 3, where the electrical current characteristic of an OECT based on the same electrolyte as in the previous measurement (FIG. 1) is shown. Indeed, the current flowing from source to drain, plotted in FIG. 3a, is modulated by the potential at the gate electrode, i.e. the device is working as a transistor with an on-off ratio exceeding two orders of magnitude, that is, generally from about 10 to about 1,000 and desirably from about 50 to about 150 in other words, the off current is about 10⁻⁶ to 10⁻⁴ amps and on current is about 10⁻⁴ to 10⁻² amps.

The transistor of the present invention shows a very high on current and a very high transconductance. The maximum transconductance (sensitivity) obtained in the organic electrochemical transistor of the present invention is above 10 mS even though the length of the channel is as large as 1 cm. This high transconductance is essential for the benefits of this device, as the transconductance is a measure for the amplification that can be obtained in this geometry. Depending upon device geometry and materials (channel polymer and electrolyte), the transconductance value is about 1 mS.

The transconductance value of the OECT is generally at least about 3 mS and preferably at least about 4.5 mS, desirably at least about 6.5 mS to about 8 mS, and often greater than about 10 mS. The highest reported value for OECT reported by the prior art is 4.5 mS. It was observed more than 10 mS. The higher the value of transconductance the better the sensor. It is noted that the value obtained is in the highest range of ever observed.

To study the mechanical response of the transistor, its gate and source were kept at the same potential to yield a configuration similar to the measurement of the flexo-current. The drain electrode was biased at −0.1 V. The same external force was applied to the transistor on the right to the device as shown in FIG. 2b. It was observed (see FIG. 3c) that the drain current follows the mechanical modulation, i.e. bending the device drives ions into the top PEDOT:PSS layer, which will modulate the conductivity of this layer and hence the current flowing from source to drain.

The drain current exceeds the flexo-current by several orders of magnitude. VVith respect to the sensitivity of the flexible organic electrochemical transistors of the present invention, it is defined as the ratio of the difference in drain current in the OECT to the difference of the flexo-current for the same amount of both voltage and force applied. The flexo-current is in the range of nano amperes as noted above. The drain current is in the range of milli ampere. So the difference between drain current in OECT and flexo-current is about 6 orders of magnitude; that is from about 10² to about 10⁶, and desirably from about 10⁴ to about 10⁵, and preferably from about 10² to about 10⁴, which is caused by the large transconductance of the underlying OECT principle. Overall, these results confirm that the OECT can work as a bending sensor

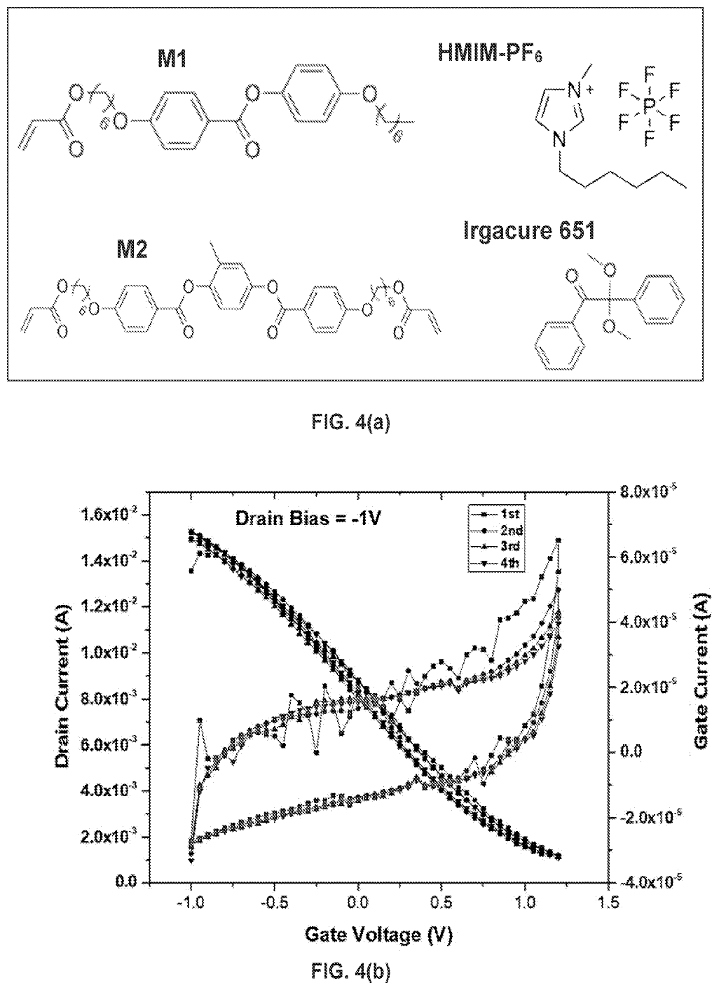

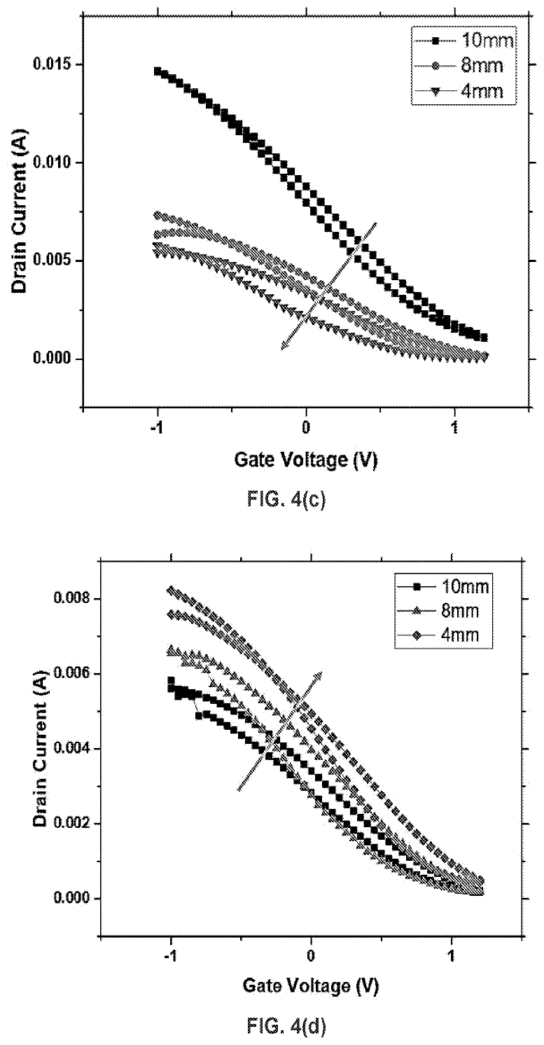

A second embodiment of the invention is shown in FIG. 4. Here, Ionic Liquid Crystal Elastomer (ILCE) shown in FIG. 4a is used as the gate electrolyte. The working mechanism is identical to the previous embodiment, but the liquid crystalline nature of the ILCE allows to control the orientation of the monomers in the film, which provides additional degrees of freedom to optimize the system. The liquid crystal can generally be nematic, or smectic, or cholesteric. It is also noted that the formation of the ILCE are well known to the art and to the literature.

FIG. 4b shows the transfer characteristic of the OECT. Besides a high transconductance, the devices show very low gate currents. FIG. 4c and d show the change in the transfer characteristic upon bending the cantilever upward (c) and downward (d). Bending the cantilever upward leads to a decrease in current, whereas a downward bend leads to an increase in current.

In summary, the invention relates to a new approach to realize highly sensitive curvature sensors. The high sensitivity is obtained by combining IEAPs and/or ILCEs with organic electrochemical transistors (OECTs) to amplify the observed flexo current and present a new class of curvature sensors that opens a new window in the field of soft robotics and sensors.

Disclosed, in further embodiments, is an ionic liquid crystal elastomer precursor composition including: a monomer; a crosslinking agent; and an ionic liquid. In some embodiments, the precursor composition further includes an initiator.

Applications include the following:
1. Flexible Organic Electronics
2. Robotics applications
3. Prosthetics
4. Artificial Skin
5. Data Glove

The invention has the following advantages:

In comparison to sensors that rely on a change in resistance due to a strain in the functional layer, the invention is less prone to cracking and hence feature a longer lifetime and larger operational window.

In contrast to fiber-based sensors, the device invented here does not need additional conversion between optical and electrical signals. Fiber-based sensors are furthermore difficult to miniaturize.

Due to the combination with the OECT, the sensor of the present invention has a sensitivity that is several orders of magnitude larger than obtained by conventional electroactive polymers.

In contrast to other bend sensors, in particular strain sensors, the working mechanism described here is able to discern between upwards and downwards bending.

The system is perfectly flexible and compatible with biological interfaces.

The sensor can be easily combined with other sensing mechanisms, i.e. mechanisms that make the device sensitive to a wide range of biomolecules such as neurotransmitters, lactic acid, or glucose.

Fabrication of OECT is straightforward and can be implemented into a roll-to-roll manufacturing process.

The large transconductance obtained in this geometry leads to an inherent amplification of the flexo-currents inside the device. Therefore, the device is highly sensitive.

While in accordance with the patent statutes, the best mode and preferred embodiment have been set forth, the scope of the invention is not limited thereto, but rather by the scope of the attached claims.

What is claimed is:

1. A flexible organic electrochemical transistor, comprising;
a layer of an ionic electroactive polymer (IEAP) or an ionic liquid crystal elastomer (ILCE); an organic semiconductor layer residing on the top of said IEAP or said ILCE layer and on the bottom of said IEAP or said ILCE layer that forms a structure having a flexo-current gain that is greater than flexo-electronic currents generated inside the IEAP layer.

2. The flexible organic electrochemical transistor according to claim 1, wherein said transistor includes a gate and a source at one end of said transistor and a drain at the other end of said transistor.

3. The flexible organic electrochemical transistor according to claim 2, wherein said IEAP compound comprises an ionic electroactive polymer, an ionic liquid, and a crosslinking agent;
wherein said ionic electroactive polymer comprises Nafion (N-(3-acetylphenyl)-4-(2-phenylethyl)thieno[3,2-b]pyrrole-5-carboxamide), Aquivion (Tetrafluoroethylene-perfluoro(3-oxa-4-pentenesulfonic acid) copolymer), PMMA (Poly (methyl methacrylate)), PVDF (Polyvinylidene fluoride), Pluronic, Polyacrylamide, PDMS (polydimethylsiloxane), poly(ethylene glycol) methyl ether acrylate and PANI (polyaniline) and polyethylene glycol)diacrylate (PEGDA), or any combination thereof;
wherein said organic semiconductor comprises P3HT (Poly(3-hexylthiophene)), p(g2T2-g4T2) (poly(2-(3,3′-bis(diethylene glycol monomethyl ether)-[2,2′-bithiophen]-5-yl))-(2-(3,3′-bis(tetraethylene glycol monomethyl ether)[2,2′-bithiophen]-5-yl))), P90 (poly{[N,N′-bis(2-octyldodecyl)naphthalene-1,4,5,8-bis(dicarboximide)-2,6-diyl]-alt-5,5′-(2,2′-bithiophene)-ran-[N,N′-bis(7-glycol)naphthalene-1,4,5,8-bis(dicarboximide)-2,6-diyl]-alt-5,5′-(2,2′-bithiophene)}), p(g2T-TT) (poly(2-(3,3-bis(2-(2-(2-methoxyethoxy)ethoxy)ethoxy)-[2,2′-bithiophen]-5-yl)thieno[3,2-b]thiophene)), P3MEEMT (poly(3-{[2-(2-methoxyethoxy)ethoxy]methyl}thiophene-2,5-diyl)), and preferably PEDOT;PSS, i.e. poly(3,4-ethylenedioxythiophene) polystyrene sulfonate, or any combination thereof.

4. The flexible organic electrochemical transistor according to claim 2, wherein said ionic electroactive polymer comprises said PEGDA.

5. The flexible organic electrochemical transistor according to claim 4, wherein said organic semiconductor comprises said PEDOT;PSS.

6. The flexible organic electrochemical transistor according to claim 2, wherein the flexo-current gain is from about 10² to about 10⁶.

7. The flexible organic electrochemical transistor according to claim 6, wherein the flexo-current gain is from about 10² to about 10⁴.

8. The flexible organic electrochemical transistor according to claim 3, wherein the flexo-current gain is from about 10² to about 10⁶.

9. The flexible organic electrochemical transistor according to claim 8, wherein the flexo-current gain is from about 10² to about 10⁴.

10. The flexible organic electrochemical transistor according to claim 5, wherein the flexo-current gain is from about 10² to about 10⁶.

11. The flexible organic electrochemical transistor according to claim 10, wherein the flexo-current gain is from about 10² to about 10⁴.

12. The flexible organic electrochemical transistor according to claim 2, wherein the transconductance sensitivity value is at least about 3 mS.

13. The flexible organic electrochemical transistor according to claim 12, wherein the transconductance sensitivity value is at least about 6.5 mS.

14. The flexible organic electrochemical transistor according to claim 3, wherein the transconductance sensitivity value is at least about 3 mS.

15. The flexible organic electrochemical transistor according to claim 14, wherein the transconductance sensitivity value is at least about 6.5 mS.

16. The flexible organic electrochemical transistor according to claim 5, wherein the transconductance sensitivity value gain is at least about 3 mS.

17. The flexible organic electrochemical transistor according to claim 16, wherein the transconductance sensitivity value gain is at least about 6.5 mS.

18. The flexible organic electrochemical transistor according to claim 5, wherein the thickness of said organic semiconductor layer residing on said IEAP is from about 50 to about 200 nanometers.

19. The flexible organic electrochemical transistor according to claim 5, wherein the thickness of said organic semiconductor layer residing on said IEAP is from about 80 to about 120 nanometers.
